(19) United States
(12) Patent Application Publication
(10) Pub. No.: US 2017/0117500 A1
(43) Pub. Date: Apr. 27, 2017

(54) DISPLAY DEVICE

(71) Applicant: Japan Display Inc., Minato-ku (JP)

(72) Inventor: Masakazu GUNJI, Tokyo (JP)

(73) Assignee: Japan Display Inc., Minato-ku (JP)

(21) Appl. No.: 15/351,264

(22) Filed: Nov. 14, 2016

(30) Foreign Application Priority Data
Oct. 27, 2015 (JP) 2015-210509

(51) Int. Cl. H01L 51/52; H01L 27/32

(52) U.S. Cl. CPC H01L 51/5228; H01L 27/3272; H01L 51/5234; H01L 27/3246; H01L 2227/323

(57) ABSTRACT

A display device includes a plurality of lower electrodes; an organic layer that is provided to cover the plurality of lower electrodes, and includes a luminescent layer; a charge generation layer that is continuously and integrally provided to cover the organic layer, and generates carriers by generating electrons and holes in response to a voltage that is applied; and upper electrodes that are provided between the plurality of lower electrodes in a plan view so as to avoid upside of a central portion of each of at least the plurality of lower electrodes, on the charge generation layer.

### CROSS-REFERENCE TO RELATED APPLICATION

The present application claims priority from Japanese application JP2015-210509 filed on Oct. 27, 2015, the content of which is hereby incorporated by reference into this application.

### BACKGROUND OF THE INVENTION

1. Field of the Invention

The present invention relates to a display device.

2. Description of the Related Art

In a display device such as an organic electro luminescence (EL) display device and the like, there is a case where an image is displayed by controlling a self-emitting element such as an organic light emitting diode (OLED) and the like by using a switching element such as a transistor and the like. There is a case where the self-emitting element such as the OLED and the like has a configuration where a layer including a luminescent layer is pinched by two electrodes. In this case, an electrode provided in a side from which light is emitted is formed from transparent conductive material.

In JP 2001-230086 A, an active drive type organic EL light emitting device of which upper electrodes are configured of a main electrode formed from transparent conductive material and an auxiliary electrode formed from low resistance material is described.

### SUMMARY OF THE INVENTION

There is a case where transparent conductive material has an electrical resistance higher than that of a metal material. There is a case where a light extraction amount is reduced by lowering the light transparency, when a thickness of an electrode formed from transparent conductive material is increased, in order to lower the electrical resistance of the electrode.

Accordingly, an object of the present invention is to provide a display device in which reduction of the light extraction amount is prevented, or to provide a display device in which power consumption is reduced.

The display device of the invention includes a plurality of lower electrodes; an organic layer that is provided to cover the plurality of lower electrodes, and includes a luminescent layer; a charge generation layer that is continuously and integrally provided to cover the organic layer, and generates carriers by generating electrons and holes in response to a voltage that is applied; and upper electrodes that are provided between the plurality of lower electrodes in a plan view so as to avoid being upside of a central portion of each of at least the plurality of lower electrodes, on the charge generation layer.

### BRIEF DESCRIPTION OF THE DRAWINGS

FIG. 1 is a perspective view of a display device according to a first embodiment of the invention.

FIG. 2 is a wiring diagram of a display panel according to the first embodiment of the invention.

FIG. 3 is a sectional view of a pixel of the display panel according to the first embodiment of the invention.

FIG. 4 is a top view of the pixel of the display panel according to the first embodiment of the invention.

FIG. 5 is a top view of a pixel of a display panel according to a modification example of the first embodiment of the invention.

FIG. 6 is a sectional view of a pixel of a display panel according to a second embodiment of the invention.

FIG. 7 is a sectional view of a pixel of a display panel according to a third embodiment of the invention.

FIG. 8 is a sectional view of a pixel of a display panel according to a fourth embodiment of the invention.

### DETAILED DESCRIPTION OF THE INVENTION

Hereinafter, the embodiments of the present invention will be described with reference to the drawings. The disclosure is merely an example, and a proper change which may readily occur to those skilled in the art while maintaining the spirit of the invention are naturally contained in the scope of the present invention. Further, since the drawings to clarify the description are merely one example, there are cases where each portion of the width, thickness, the shape or the like is schematically represented, compared to the actual aspect, and the interpretation of the present invention not limiting. In addition, in the present specification and the drawings, by denoting components similar to those previously described with reference to earlier figures with the same reference numerals, there is possible to appropriately omit the detailed description.

### First Embodiment

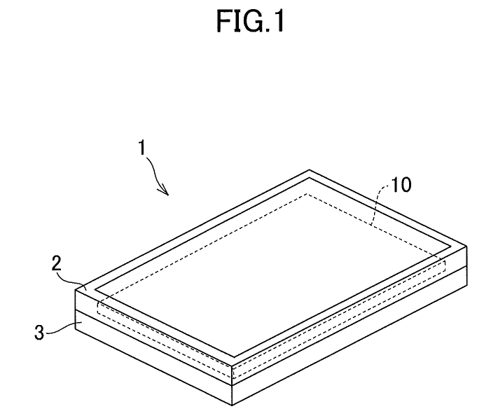

FIG. 1 is a perspective view illustrating a display device 1 according to a first embodiment of the invention. The display device 1 is configured by a display panel 10 fixed to be pinched between an upper frame 2 and a lower frame 3.

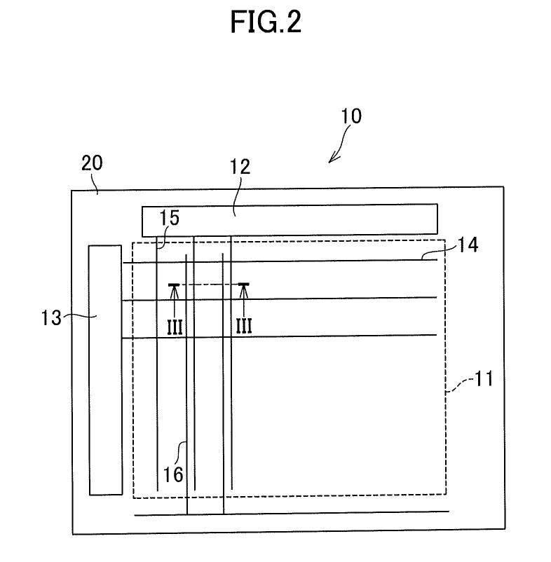

FIG. 2 is a wiring diagram of the display panel 10 according to the first embodiment of the invention. The display panel 10 controls each pixel provided in a display region 11 in a matrix shape, by a video signal drive circuit 12 and a scanning signal drive circuit 13, and displays an image. Here, the video signal drive circuit 12 is a circuit that generates a video signal to be transmitted to each pixel, and transmits the signal. In addition, the scanning signal drive circuit 13 is a circuit that generates a scanning signal to a thin film transistor (TFT) provided in the pixel, and transmits the signal. In the drawing, the video signal drive circuit 12 and the scanning signal drive circuit 13 are illustrated as circuits formed in two locations. However, the circuits may be also incorporated into one integrated circuit (IC), and may be also formed on three or more locations by dividing the circuits.

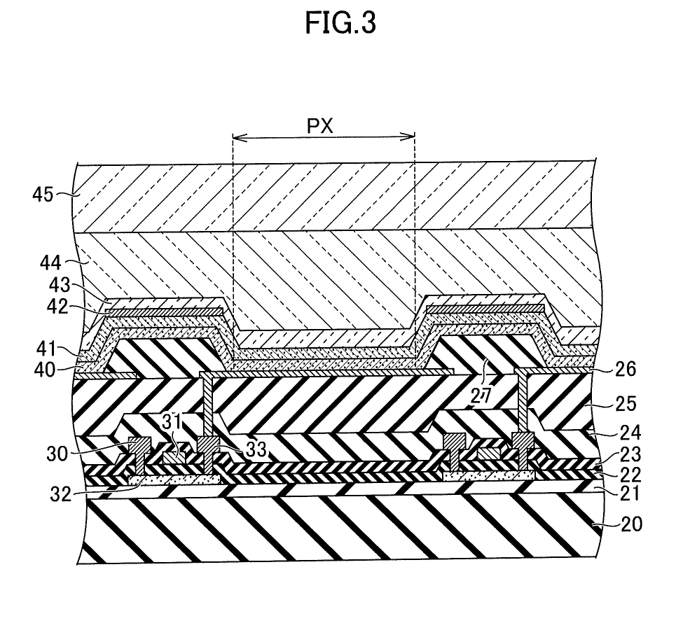

FIG. 3 is a sectional view of a pixel of the display device 1 according to the first embodiment of the invention. A substrate 20 is disposed on the lowermost layer of the display panel 10. The substrate 20 is formed from glass, artificial resin, or the like. A base film 21 is formed from SiN, SiO₂, or the like on the substrate 20. A semiconductor layer 32 that electrically connects a drain electrode 30 and a source electrode 33 of a driving transistor is formed on the base film 21. The semiconductor layer 32 is formed from the polycrystalline silicon. The semiconductor layer 32 may be formed from the amorphous silicon or the like. A first insulation layer 22 is formed from SiN, SiO₂, or the like on the base film 21 and the semiconductor layer 32. Agate electrode 31 of the driving transistor by metal material is formed on the first insulation layer 22. A second insulation layer 23 is formed from SiN, SiO₂, or the like on the first insulation layer 22 and the gate electrode 31. A through hole that reaches up to the semiconductor layer 32 is provided, and the drain electrode 30 and the source electrode 33 of the driving transistor are formed from metal material, on the second insulation layer 23 and the first insulation layer 22. An interlayer insulation film 24 is formed from SiN, SiO₂, or the like on the drain electrode 30, the source electrode 33, and the second insulation layer 23. A planarization film 25 is formed by an insulator such as insulation film resin and the like such as acrylic, epoxy, and the like on the interlayer insulation film 24.

A plurality of lower electrodes 26 is formed from metal material on the planarization film 25. The lower electrode 26 becomes an anode of the OLED. The lower electrode 26 is electrically connected to the source electrode 33 of the driving transistor, via the through hole provided on the planarization film 25 and the interlayer insulation film 24. The lower electrodes 26 are formed to be separated from each other for each pixel. In the display device 1 according to the embodiment, a corresponding pixel is emitted by applying a voltage to a specific lower electrode 26 among the plurality of lower electrodes 26 such that an image is displayed.

A pixel separation film 27 is formed from photosensitive resin such as acrylic, polyimide, and the like, or inorganic material such as SiN, SiO₂, and the like on the planarization film 25 and the lower electrode 26. The pixel separation film 27 is formed from insulation material to cover end portions of the plurality of lower electrodes 26. The pixel separation film 27 that is an insulation film is provided between end portions of the lower electrode 26 and an upper electrode 42 described below such that a short circuit between the electrodes is prevented. In addition, a pixel region PX is defined in the pixel separation film 27, as described below.

An organic layer 40 is formed to cover the plurality of lower electrodes 26 on the plurality of lower electrodes 26. The organic layer 40 is a layer including the luminescent layer. The organic layer 40 is a layer in which a hole transporting layer (or hole injection layer and hole transporting layer), a luminescent layer, and an electron transporting layer (or electron transporting layer and electron injection layer) are sequentially laminated, from the lower electrode 26 side. Respective layers maybe formed from organic semiconductor material. A region which is not covered with the pixel separation film 27, and is in contact with the organic layer 40 among the lower electrodes 26 is referred as the pixel region PX. A portion contributing light emission in the organic layer 40 is mainly a portion provided in the pixel region PX. The holes flow from the hole transporting layer and the electrons flow from the electron transporting layer, into the organic layer 40 provided in the pixel region PX. Accordingly, recombination of the electrons and the holes occurs in the luminescent layer, the organic material for forming the luminescent layer is excited, and light is emitted at the time of transitioning from a high energy level to a low energy level.

A charge generation layer 41 that is continuously and integrally provided to cover the organic layer 40, and generates carriers by generating the electrons and the holes in response to a voltage that is applied is formed on the organic layer 40. The charge generation layer 41 may be formed from the organic semiconductor material. It is preferable that the charge generation layer 41 is hexacyano-hexaazatriphenylene (HATCN) and tetrafluoro-tetracyanoquinodimethane (F4TCNQ) in a case of organic material, and the charge generation layer 41 is vanadium oxide (V₂O₅) and molybdenum oxide (MoO₃) in a case of inorganic material. In addition, the upper electrodes 42 are provided between the plurality of lower electrodes 26 in a plan view so as to avoid the upside of the central portion of each of at least a plurality of lower electrodes 26, on the charge generation layer 41. The upper electrode 42 according to the embodiment is provided to not overlap the pixel region PX, and does not interfere light emitted from the organic layer 40. Therefore, in the display device 1 according to the embodiment, reduction of the light extraction amount is prevented. However, the upper electrode 42 may be provided to avoid the upside of the central portion of the lower electrode 26. In this case, it is possible to sufficiently extract the light emitted from the organic layer 40. Furthermore, if on the pixel separation film 27, the upper electrode 42 may be also overlapped with the lower electrode 26 in a plan view.

The upper electrode 42 may be formed from metal. In a case where the upper electrode is provided to cover the organic layer 40 on the pixel region PX, it is necessary to form the upper electrode with transparent conductive material such as indium tin oxide (ITO), indium zinc oxide (IZO), and the like. However, although the upper electrode is formed by using the transparent conductive material, the attenuation of light by the transparent conductive material is inevitable. At this point, in the display device 1 according to the embodiment, it is possible to form the upper electrode 42 by thick metal enough not to have the light transparency, and since it is possible to lower the electrical resistance, compared to a case where the upper electrode is formed from the transparent conductive material, the power consumption is reduced. It is also possible to form the upper electrode 42 with thick transparent conductive material having a relatively small electrical resistance. Even in this case, it is also possible to reduce the power consumption of the display device 1.

In addition, the upper electrode 42 according to the embodiment is provided above the pixel separation film 27. Since the pixel separation film 27 is provided to cover end portions of the lower electrode 26, the upper electrode 42 is provided to be overlapped with the end portions of the lower electrode 26 in a plan view. It is mentioned that the upper electrode 42 may be not provided on a region on which the pixel separation film 27 does not exist, in a plan view. By disposing the upper electrode 42 as described above, it is possible to avoid overlapping of the upper electrode 42 with the pixel region PX, and improve the light extraction amount of the display device 1. In addition, by disposing transparent electrode material on the pixel region PX, it is possible to avoid the attenuation of light.

The charge generation layer 41 generates a pair of electron and hole in response to a voltage applied between the lower electrode 26 and the upper electrode 42 formed for each pixel. The generated holes flow toward the upper electrode 42. In addition, the generated electrons flow toward the electron transporting layer (or electron injection layer) that is the topmost layer of the organic layer 40 provided in the lower electrode 26 side. The flow of the carriers (electrons or holes) in the charge generation layer 41 will be briefly described as follows. In a case where a first pair of electrons and holes is generated from the lower electrode 26 side, and a second pair of electrons and holes is generated from the upper electrode 42 side, the first pair of the holes flows toward the upper electrode 42, and the second pair of the electrons flows toward the lower electrode 26. Accordingly, the first pair of the holes and the second pair of the electrons are recombined and disappear. Meanwhile, the first pair of the electrons reaches the lower electrode 26, and the second pair of the holes reaches the upper electrode 42. As described above, even in a case where the mobility of carriers is relatively low in the organic semiconductor material, it is possible to flow actually a current from the lower electrode 26 to the upper electrode 42, by intervening the recombination. Therefore, although the lower electrode 26 and the upper electrode 42 are not provided to face each other by pinching the organic layer 40, it is possible to flow the current from the lower electrode 26 to the upper electrode 42.

A sealing film 43 is formed on the charge generation layer 41 and the upper electrode 42. The sealing film 43 is formed from SiN, SiO, or a laminated film thereof. A filler 44 is filled, and sealed by attaching an oppose substrate 45 on the sealing film 43. A black matrix, a color filter, and a polarizing plate may be also provided on the front surface or the rear surface of the oppose substrate 45. In addition, a touch panel may be also provided in the front surface of the oppose substrate 45.

The OLED formed by the organic layer 40 may also be a so-called tandem type. That is, a first OLED is formed by sequentially laminating the hole transporting layer, a first luminescent layer, and the electron transporting layer, and a second OLED may be also formed by forming the charge generation layer on the electron transporting layer and by sequentially laminating the hole transporting layer, a second luminescent layer, and the electron transporting layer. Furthermore, a third OLED may be also formed by laminating the charge generation layer, and by sequentially laminating the hole transporting layer, a third luminescent layer, and the electron transporting layer. By adjusting the luminescent color of a plurality of OLEDs that are laminated, it is possible to set the entirety of the tandem type OLED to a white luminescent color. In this case, it is possible to perform full color image display by providing a color filter on the oppose substrate 45 or the like.

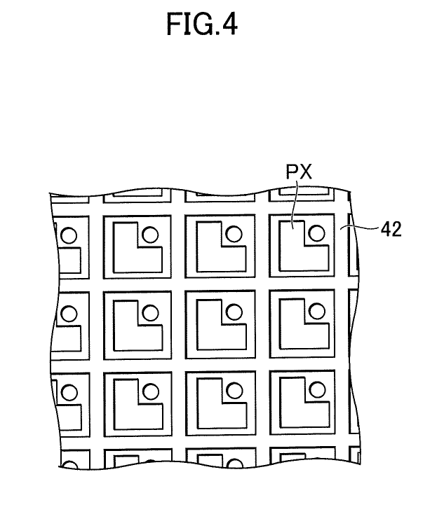

FIG. 4 is a top view of a pixel of the display panel 10 according to the first embodiment of the invention. FIG. 4 illustrates a positional relationship of the pixel region PX and the upper electrode 42. The upper electrodes 42 according to the embodiment are provided in a matrix shape in a plan view. Since the upper electrode 42 is provided to surround the pixel region PX, and respective distances from two long sides of the pixel region PX to the upper electrode 42 are the same degree, it is possible to emit light from the organic layer 40 of the pixel region PX at any location in a condition of the same degree. Therefore, uniform display quality is obtained for every pixel.

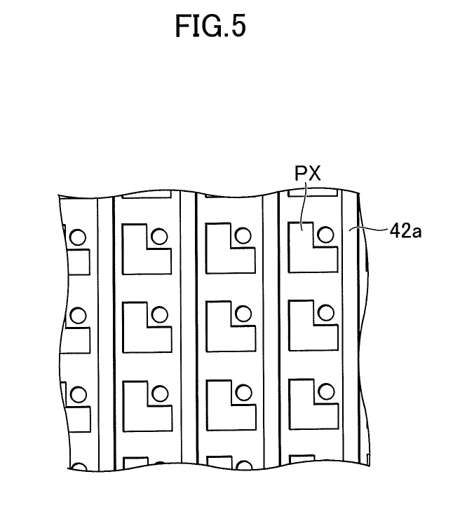

FIG. 5 is a top view of a pixel of a display panel 10 according to a modification example of the first embodiment of the invention. Stripe upper electrodes 42a according to the modification example are provided in parallel between the pixel regions PX. Even in a case where the stripe upper electrodes 42a are provided as the modification example, without overlapping the pixel region PX and the stripe upper electrode 42a, the light extraction amount is improved. In addition, since it is possible to lower the electrical resistance by forming or the like the stripe upper electrode 42a with metal, it is possible to lower the power consumption of the display device 1. In addition, since the stripe upper electrode 42a can be formed by a single film-forming process, the display device 1 according to the modification example can be manufactured by fewer processes, and manufactured in a shorter time and at a lower cost, compared to a case where the upper electrode 42 of the matrix shape required for at least two film-forming processes is adopted.

### Second Embodiment

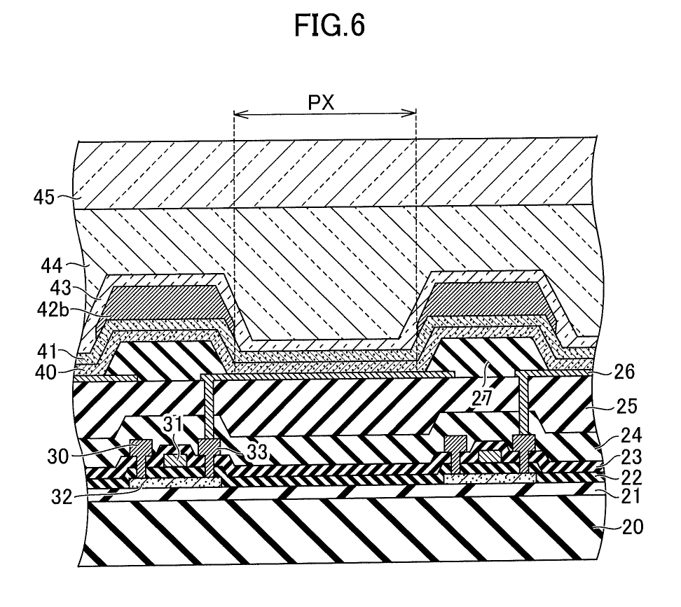

FIG. 6 is a sectional view of a pixel of the display panel 10 according to a second embodiment of the invention. The display panel 10 according to the embodiment includes an expanded upper electrode 42b above the pixel separation film 27, on the charge generation layer 41. For a configuration other than the expanded upper electrode 42b, the display panel 10 according to the embodiment has the same configuration as the display panel 10 according to the first embodiment.

The expanded upper electrode 42b is formed to reach a slope portion formed by the pixel separation film 27 so as not to overlap the pixel region PX in a plan view. Since the expanded upper electrode 42b is formed thicker than the upper electrode 42 according to the first embodiment, an area being in contact with the charge generation layer 4l is wider. Therefore, the electrical resistance becomes smaller such that the power consumption of the display device 1 is further reduced.

### Third Embodiment

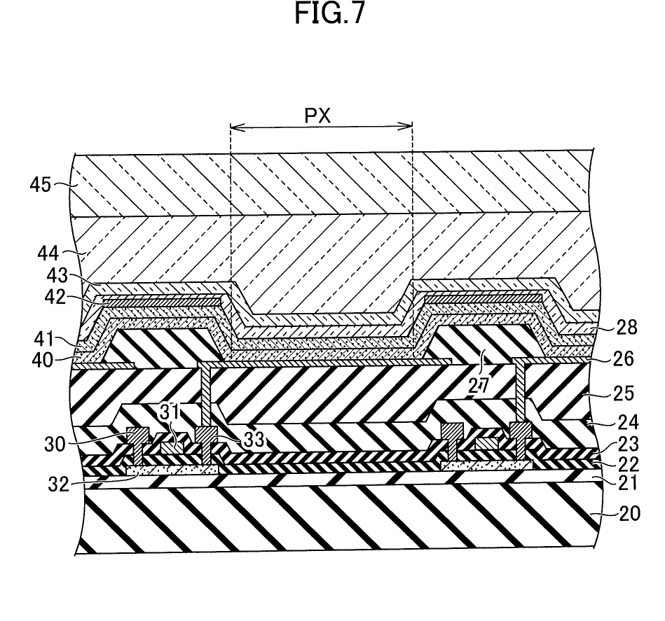

FIG. 7 is a sectional view of a pixel of the display panel 10 according to a third embodiment of the invention. The display panel 10 according to the embodiment includes an ultraviolet ray shielding film 28 on the upper electrode 42 and the charge generation layer 41. The sealing film 43 is formed on the ultraviolet ray shielding film 28. For a configuration other than the ultraviolet ray shielding film 28, the display panel 10 according to the embodiment has the same configuration as the display panel 10 according to the first embodiment.

The ultraviolet ray shielding film 28 is provided to cover the organic layer 40 above each of at least the plurality of lower electrodes 26. The ultraviolet ray shielding film 28 according to the embodiment is continuously and integrally provided to cover the entirety of a display region of the display panel 10. In addition, the sealing film 43 is continuously and integrally provided to cover the upper electrode 42 and the ultraviolet ray shielding film 28.

There is a case where the sealing film 43 is formed by the plasma-enhanced chemical vapor deposition. In the plasma-enhanced chemical vapor deposition process, since there is a case where ultraviolet rays are generated, there is a concern that the organic layer 40 is deteriorated due to irradiation of the ultraviolet rays. In the display panel 10 of the related art, there is a case where the upper electrode is formed from transparent conductive material on the entirety of the display region, and deterioration of the organic layer 40 formed under the upper electrode is prevented because the ultraviolet rays are shielded by the upper electrode. At this point, in the display panel 10 according to the embodiment, the ultraviolet ray shielding film 28 is formed before performing the process for forming the sealing film 43. With this, even in a case where the sealing film 43 formed by the plasma-enhanced chemical vapor deposition is formed to cover the organic layer 40 without forming the upper electrode 42 above the central portion of the lower electrode 26, the deterioration of the organic layer 40 is prevented.

### Fourth Embodiment

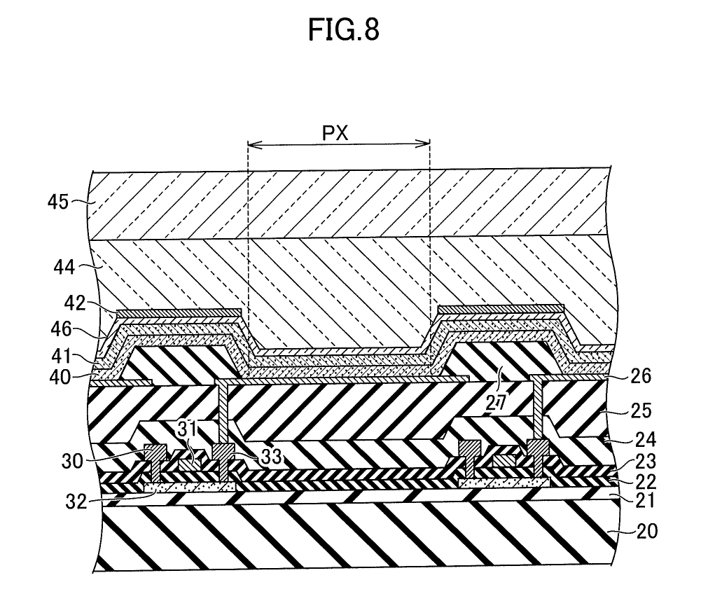

FIG. 8 is a sectional view of a pixel of the display panel 10 according to a fourth embodiment of the invention. The display panel 10 according to the embodiment includes a silver thin film 46 on the charge generation layer 41. In addition, the display panel 10 according to the embodiment does not include the sealing film 43. For a configuration other than the silver thin film 46 and the sealing film 43, the display panel 10 according to the embodiment has the same configuration as the display panel 10 according to the first embodiment. Furthermore, inert noble gas such as nitrogen gas or the like instead of the filler 44 may be filled.

The silver thin film 46 is a light transmissive metal film that is continuously and integrally provided to cover the organic layer 40. The silver thin film 46 protects the organic layer 40 and is formed between the upper electrode 42 and the charge generation layer 41 such that the conductivity can be also improved. The silver thin film 46 may be also replaced with a metal film such as a magnesium silver thin film and the like. It is preferable that the silver thin film 46 or the like is formed by vapor deposition or PVD. It is also considered that the silver thin film 46 or the like is formed by plasma CVD. However, there is a concern that the ultraviolet rays generated in a manufacturing process cause deterioration of the organic layer 40.

The display panel 10 according to the embodiment does not include a film formed by the plasma-enhanced chemical vapor deposition above each of at least the plurality of lower electrodes 26. Particularly, the display panel 10 according to the embodiment does not include the sealing film 43 formed by the plasma-enhanced chemical vapor deposition. Therefore, there is no concern that the organic layer 40 is deteriorated by generating the ultraviolet rays in the plasma-enhanced chemical vapor deposition process, and it is possible to maintain high quality of the organic layer 40.

It is preferable that the oppose substrate 45 according to the embodiment is adhered with a frit glass in a frame region. By adhering the oppose substrate 45 with the frit glass, it is possible to obtain high sealing property, and prevent moisture or the like from entering the organic layer 40, together with protection by the silver thin film 46.

Based on the display device 1 described above as an embodiment of the present invention, all of display devices that can be appropriately modified by those skilled in the art are, as long as including the spirit of the present invention, within the scope of the present invention. For example, the shape of the pixel region may not be an L-shape, may be a rectangular shape, and may be a polygonal shape.

Within the spirit of the present invention, those skilled in the art can conceive various changes and modifications and the changes and modifications also should therefore be seen as within the scope of the present invention. For example, for each embodiment described above, an addition and deletion of components or design change, or, an addition and omission of a step, or condition change, which have been appropriately given by those skilled in the art, as long as they include the gist of the present invention, are included in the scope of the present invention.

In addition, what is clear from the specification with respect to other advantageous effects provided by aspects described in the present embodiment, or what may appropriately occur to those skilled in the art, is intended to be provided naturally by the present invention.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a plurality of lower electrodes;
an organic layer that is provided to cover the plurality of lower electrodes, and includes a luminescent layer;
a charge generation layer that is continuously and integrally provided to cover the organic layer, and generates carriers by generating electrons and holes in response to a voltage that is applied; and
upper electrodes that are provided between the plurality of lower electrodes in a plan view so as to avoid upside of a central portion of each of at least the plurality of lower electrodes, on the charge generation layer.

2. The display device according to claim 1, further comprising:
a pixel separation film formed from insulation material to cover end portions of the plurality of lower electrodes,
wherein the upper electrode is provided above the pixel separation film.

3. The display device according to claim 2,
wherein the upper electrode is formed to reach a slope portion formed by the pixel separation film.

4. The display device according to claim 1, further comprising:
an ultraviolet ray shielding film that is provided to cover the organic layer above each of at least the plurality of lower electrodes; and
a sealing film that is continuously and integrally provided to cover the upper electrode and the ultraviolet ray shielding film.

5. The display device according to claim 1,
wherein a film formed by plasma-enhanced chemical vapor deposition is not provided above each of at least the plurality of lower electrodes.

6. The display device according to claim 5, further comprising:
a light transmissive metal film that is continuously and integrally provided to cover the organic layer.

7. The display device according to claim 1,
wherein the upper electrode is formed from metal.

8. The display device according to claim 1,
wherein the upper electrode is provided in a matrix form in a plan view.

9. A display device comprising:
a plurality of lower electrodes;
an organic layer that is provided to cover the plurality of lower electrodes, and includes a luminescent layer;
a charge generation layer that is continuously and integrally provided to cover the organic layer, and generates carriers by generating electrons and holes in response to a voltage that is applied;
a pixel separation film that is formed from insulation material to cover end portions of the plurality of lower electrodes; and
an upper electrode that is provided on the charge generation layer,
wherein the upper electrode is not provided on a region on which the pixel separation film is not present in a plan view.

10. The display device according to claim 9,
wherein the upper electrode is formed to reach a slope portion formed by the pixel separation film.

11. The display device according to claim 9, further comprising:
an ultraviolet ray shielding film that is provided to cover the organic layer above each of at least the plurality of lower electrodes; and
a sealing film that is provided to cover the upper electrode and the ultraviolet ray shielding film.

12. The display device according to claim 9,
wherein inert gas is disposed on the upper electrode and the charge generation layer.

13. The display device according to claim 12, further comprising:
a light transmissive metal film configured to cover the organic layer.

14. The display device according to claim 9,
wherein the upper electrode is formed from metal.

15. The display device according to claim 9,
wherein the upper electrode is provided in a matrix form in a plan view.
